(19) United States
(12) Patent Application Publication
(10) Pub. No.: US 2025/0169034 A1
(43) Pub. Date: May 22, 2025

(54) COOLING SYSTEM AND COMMUNICATION APPARATUSES INCLUDING THE SYSTEM

(71) Applicant: Wistron Corporation, New Taipei City (TW)

(72) Inventors: Wen-Hua ZHANG, New Taipei City (TW); I-Chen HSU, New Taipei City (TW); Shih-Chang CHEN, New Taipei City (TW); Cheng-Ying WU, New Taipei City (TW); Kuo-Hua PENG, New Taipei City (TW); Chien-Jung CHIU, New Taipei City (TW)

(21) Appl. No.: 18/641,872

(22) Filed: Apr. 22, 2024

(30) Foreign Application Priority Data
Nov. 17, 2023 (TW) 112144652

(51) Int. Cl. H05K 7/20

(52) U.S. Cl. CPC H05K 7/20272; H05K 7/20263

(57) ABSTRACT

A cooling system is adapted to a communication apparatus. The cooling system includes heat sink fins, a cooling fluid channel, and a cooling fluid drive module. The cooling fluid channel is arranged between the heat sink fins and the transceiver modules. The cooling fluid drive module supplies cooling fluid, allowing the cooling fluid to flow through the cooling fluid channel to cool the transceiver modules. This resolves the issue of excessive heat generated during the operation of the transceiver modules.

### CROSS-REFERENCE TO RELATED APPLICATION

This non-provisional application claims priority under 35 U.S.C. § 119 (a) to patent application No. 112144652 filed in Taiwan, R.O.C. on Nov. 17, 2023, the entire contents of which are hereby incorporated by reference.

### BACKGROUND

### Technical Field

The present disclosure relates to a cooling system and a communication apparatus including the system, and in particular, to a cooling system using cooling fluid to cool a transceiver module and a communication apparatus including the system.

### Related Art

A transceiver module plays an important role in an optical communication networking apparatus for data transmission. Due to the presence of some heat-generating components within the transceiver module, such as a fiber transceiver element, a laser packaging element, and a microprocessor, which generate considerable heat during running.

In another aspect, as network communication requirements keep increasing, a transmission capability of the transceiver module has risen from existing 800 G to 1.6 T, or even 3.2 T. However, as the transmission capability increases, heat generated by the transceiver module increases accordingly, for example, heat generated at 1.6 T has exceeded 30 W. Therefore, heat accumulated from the transceiver modules within a communication apparatus is already considerable. When a plurality of communication apparatuses operate simultaneously, heat generated by all the transceiver modules is remarkable.

In the prior art, air cooling technologies have been used to cool transceiver modules using heat sinks. For example, a heat sink fin is directly mounted on a metal cage, or a thin heat pipe is placed between two metal cages, and heat is transferred to a heat sink fin on a rear side or below. However, such air cooling techniques that simply use a heat sink fin may not be sufficient to meet the needs of high-speed network transmission (for example, a transmission rate exceeding 800 G).

### SUMMARY

In view of this, embodiments of the present disclosure provide a cooling system and a communication apparatus including the system, which use cooling fluid to cool the transceiver module. This not only addresses the shortcomings of existing technologies but also meets the increasing heat dissipation demands for future high-speed network transmissions

A cooling system in an embodiment of the present disclosure is used for cooling at least one transceiver module. The cooling system includes (not only limited to) a heat sink fin, a cooling fluid channel, and a cooling fluid drive module. The cooling fluid channel is arranged between the heat sink fin and the transceiver module. The cooling fluid drive module is connected to the cooling fluid channel. The cooling fluid drive module comprises a fluid circulation drive member, a fluid inlet channel, and a fluid outlet channel; an end of the fluid inlet channel and an end of the fluid outlet channel are respectively connected to two ends of the cooling fluid channel, and an another end of the fluid inlet channel and an another end of the fluid outlet channel are connected to the fluid circulation drive member.

A communication apparatus in an embodiment of the present disclosure includes a cooling system and a circuit board. The circuit board includes at least one transceiver module. The cooling system includes (not only limited to) a heat sink fin, a cooling fluid channel, and a cooling fluid drive module. The cooling fluid channel is arranged between the heat sink fin and the transceiver module. The cooling fluid drive module is connected to the cooling fluid channel. The cooling fluid drive module comprises a fluid circulation drive member, a fluid inlet channel, and a fluid outlet channel; an end of the fluid inlet channel and an end of the fluid outlet channel are respectively connected to two ends of the cooling fluid channel, and an another end of the fluid inlet channel and an another end of the fluid outlet channel are connected to the fluid circulation drive member.

A cooling system in an embodiment of the present disclosure is used for cooling a plurality of transceiver modules configured in multi-tiered arrangement. The system comprising (not only limited to): a plurality of heat sink fins, a plurality of cooling fluid channels, and a cooling fluid drive module. The cooling fluid drive module is connected to the plurality of cooling fluid channels. The plurality of cooling fluid channels are respectively arranged with the plurality of heat sink fins, and one of the plurality of cooling fluid channels is sandwiched between one tier of the plurality of transceiver modules and one of the plurality of heat sink fins.

In summary, for the cooling system and the communication apparatus including the system according to some embodiments can solve the problem of high heat generated during high-speed network transmission by providing a cooling fluid channel on the transceiver module and using the cooling fluid to flow through the channel to cool the transceiver module.

### BRIEF DESCRIPTION OF THE DRAWINGS

FIG. 1 is a three-dimensional schematic diagram of a communication apparatus according to an embodiment of the present disclosure.

FIG. 2A is a schematic diagram of a cooling system according to a first embodiment of the present disclosure.

FIG. 2B is a cross-sectional view of a line segment AA in FIG. 2A.

FIG. 3 is a partial enlarged view of a cooling system according to the first embodiment of the present disclosure.

FIG. 4 is a schematic diagram of a cooling system according to a second embodiment of the present disclosure.

FIG. 5 is a schematic diagram of a cooling system according to a third embodiment of the present disclosure.

FIG. 6 is a cross-sectional view of a line segment BB in FIG. 5.

FIG. 7 is a schematic diagram of a cooling system according to a fourth embodiment of the present disclosure.

FIG. 8 is a schematic diagram of a cooling system according to a fifth embodiment of the present disclosure.

FIG. 9 is a schematic diagram of a cooling system according to a sixth embodiment of the present disclosure.

### DETAILED DESCRIPTION

Various embodiments are set out below for detailed description. However, the embodiments are provided for illustrative purposes only and do not limit the scope of the present disclosure. In addition, some components in the embodiments may be omitted from the drawings in order to clearly illustrate technical features of the present disclosure. Furthermore, the same symbols are used in all the accompanying drawings to indicate the same or similar components, and the accompanying drawings of the present disclosure are intended only as schematic illustrations, which may not be drawn to scale, and not all details may be fully shown in the accompanying drawings.

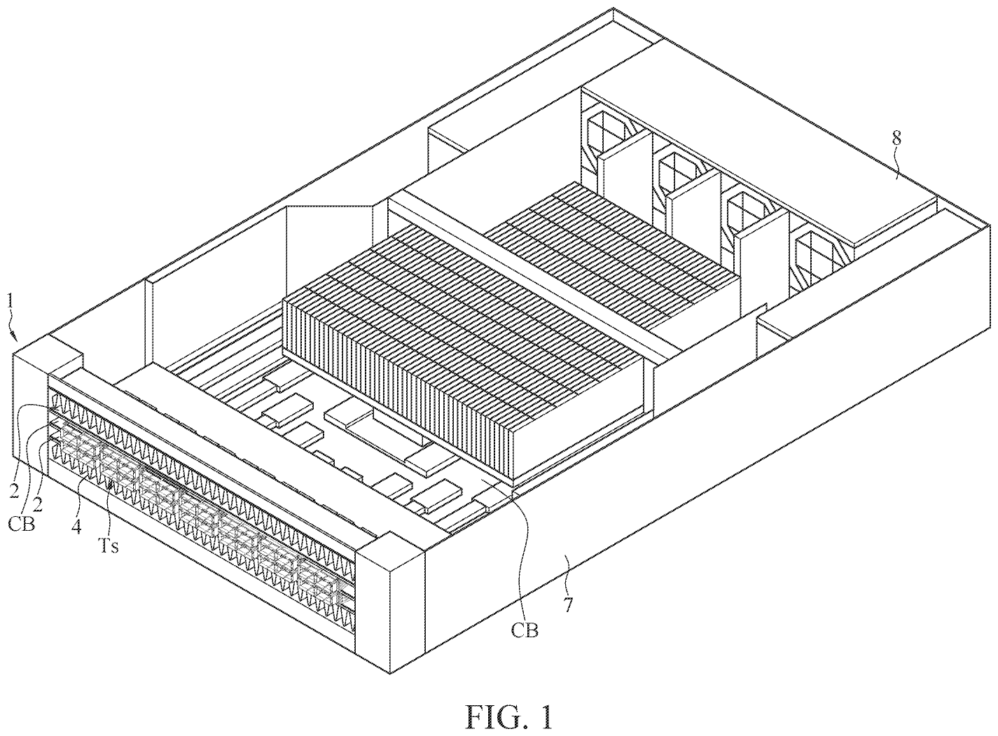

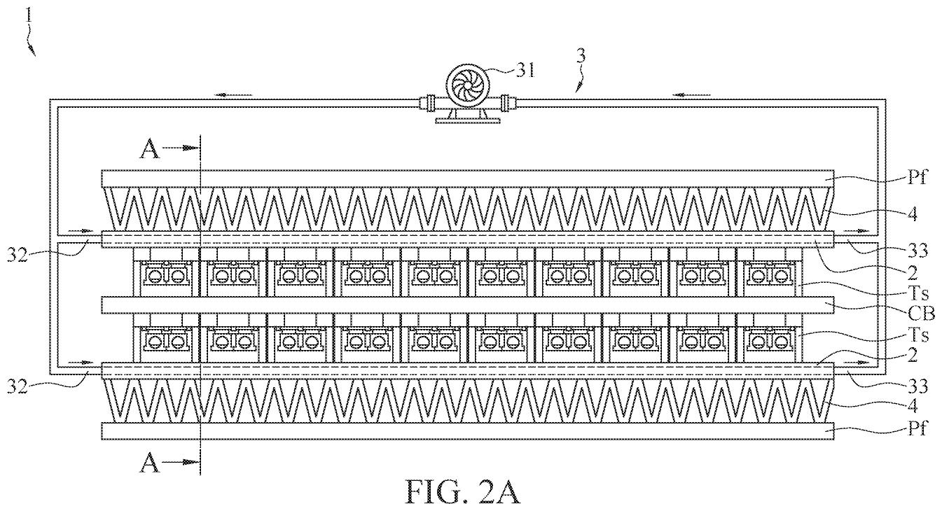

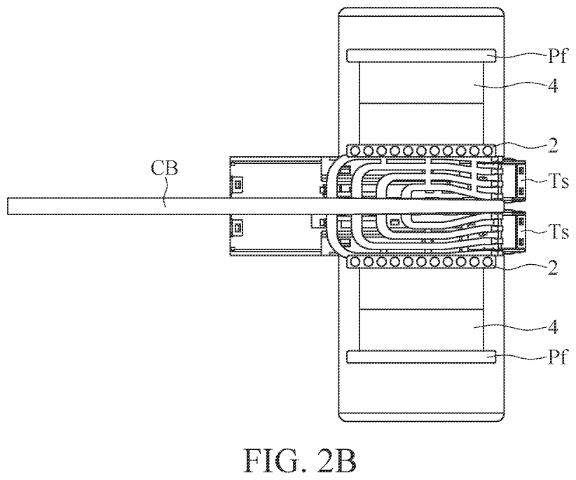

Refer to FIG. 1, FIG. 2A, and FIG. 2B first. FIG. 1 is a three-dimensional schematic diagram of a communication apparatus according to an embodiment of the present disclosure. FIG. 2A is a schematic diagram of a cooling system according to a first embodiment of the present disclosure. FIG. 2B is a cross-sectional view of a line segment AA in FIG. 2A. In an embodiment of the communication apparatus, as shown in FIG. 1, four fans 8 and a power supply (not shown in the figure) are configured on one side of a housing 7, and a circuit board CB and a cooling system 1 are configured on the other side. The circuit board CB includes a plurality of transceiver modules Ts. The transceiver modules Ts include, but not limited to, transceiver cages, which are arranged along an upper surface and a lower surface of a side end of the circuit board CB, and are electrically connected to the circuit board CB.

In some embodiments, the circuit board CB is mainly configured to perform a switch function. The circuit board CB may include (but not limited to) an on-board optical interconnect module, co-packaged optics (CPO), resistors, capacitors, inducers, and heat sinks, and other electronic components. The co-packaged optics may be connected to the transceiver modules Ts through circuit board traces, cables, circuit backplanes, and optical fibers (not shown in the figure). In other embodiments, the transceiver modules Ts may also be referred to as connectors, adaptors or ports, which may be used for plugging of, for example, a QSFP optical transceiver, a QSFP+ optical transceiver, a QSFP28 optical transceiver, an OSFP optical transceiver, and a QSFP-DD optical transceiver.

As shown in these figures, the plurality of transceiver modules are arranged in two tiers on two corresponding surfaces of the circuit board CB. In some embodiments, the cooling system 1 includes two cooling fluid channels 2 and a cooling fluid drive module 3. One cooling fluid channel 2 is disposed on a side of the upper transceiver modules Ts, while another cooling fluid channel 2 is disposed on a side of the lower transceiver modules Ts. However, the cooling fluid channels 2 may be attached to the outer surfaces of the transceiver modules Ts by welding, screwing, gluing or mechanical coupling. In other embodiments, the cooling fluid channels 2 and the transceiver modules Ts can be integrally formed.

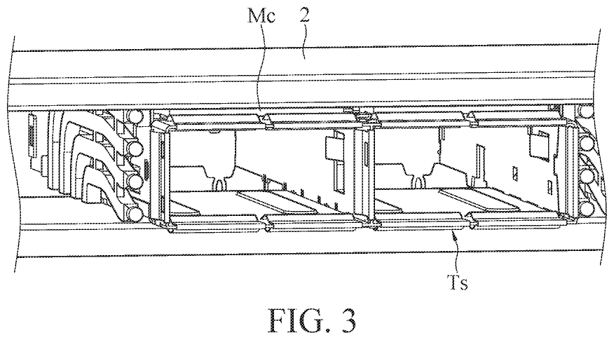

Refer to FIG. 3 together, which is a partial enlarged view of a cooling system according to the first embodiment of the present disclosure. Preferably, a thermal interface material Mc may be sandwiched between the transceiver modules Ts and the cooling fluid channel 2, and is configured to reduce air gaps between the two, thereby promoting a heat conduction effect. In some embodiments, the thermal interface material Mc may be a thermal grease, a thermal gel, a thermal pad, a Phase change material, a Phase change metal alloy, a thermal conductive adhesive, or the like. For example, the thermal interface material Mc may be a composite material of materials selected from materials having characteristics such as high heat conductivity, high flexibility, compressibility, elasticity, insulating performance, wear resistance, and the like. In one embodiment, it is generally in the form of a sheet, and may be formed between the transceiver modules Ts and the cooling fluid channel 2 in a manner such as lamination, coating, drop casting, spreading, or printing.

The cooling fluid drive module 3 includes a fluid circulation drive member 31, a fluid inlet channel 32, and a fluid outlet channel 33. An end of the fluid inlet channel 32 and an end of the fluid outlet channel 33 are respectively connected to two ends of the cooling fluid channel 2, and an another end of the fluid inlet channel 32 and an another end of the fluid outlet channel 33 are connected to the fluid circulation drive member 31. The fluid circulation drive member 31 is used to drive the cooling fluid to circulate through the fluid inlet channel 32, the cooling fluid channel 2, and the fluid outlet channel 33.

In some embodiments, the fluid circulation drive member 31 may be a vane type liquid pump, and the cooling fluid may be a refrigerant, pure water, ethylene glycol, propylene glycol or their combination. The cooling fluid is not limited to a liquid, and may be a low-temperature gas, for example, a liquid gas such as nitrogen, carbon dioxide, helium, hydrogen, or the like. In other embodiments, the cooling fluid drive module 3 may further include a reservoir and a heat exchanger (not shown in the figure). The reservoir may store a sufficient amount of cooling fluid, to ensure that the cooling fluid drive module 3 can continuously supply the cooling fluid to the cooling fluid channel 2. The heat exchanger may be a heat sink with a fan, and can further dissipate heat for the circulating cooling fluid. In other embodiments, the heat exchanger may be a chiller, and may further adjust a temperature of the cooling fluid to a lower temperature, so that the transceiver module Ts can operate at a temperature below room temperature.

In addition, as shown in FIG. 2A and FIG. 2B, a plurality of heat sink fins 4 are disposed on a side of the cooling fluid channel 2 relative to the transceiver modules Ts, and are preferably wavy fins. Through the heat sink fins 4, heat exchange may be directly performed on the cooling fluid channel 2. In other embodiments, the heat sink fins 4 may be plate-shaped (such as flat, triangular, or parabolic), or column-shaped (such as cylindrical, square, or hexagonal). In addition, in some embodiments, a fixed board Pf is disposed on one side of the heat sink fins 4, that is, a side away from the transceiver modules Ts, may be a metal or plastic thin board, and is used to secure the heat sink fins 4, to maintain the heat sink fins in a specific configuration.

Further, when the transceiver modules Ts generates heat, the heat is transferred to the cooling fluid channel 2, and at least a part of the heat is absorbed by the cooling fluid in the channel, while another part is directly transferred to the heat sink fins 4 through the wall of the cooling fluid channel 2. Subsequently, the heat within the cooling fluid is also transferred to the wavy fins on the cooling fluid channel 2 through the wall of the cooling fluid channel 2, and then dispersed into the air. In particular, in some embodiments, forced convection can be induced by the fans 8 (see FIG. 1) in the housing 7. When an airflow passes through the heat sink fins 4, heat may be expelled from the housing 7.

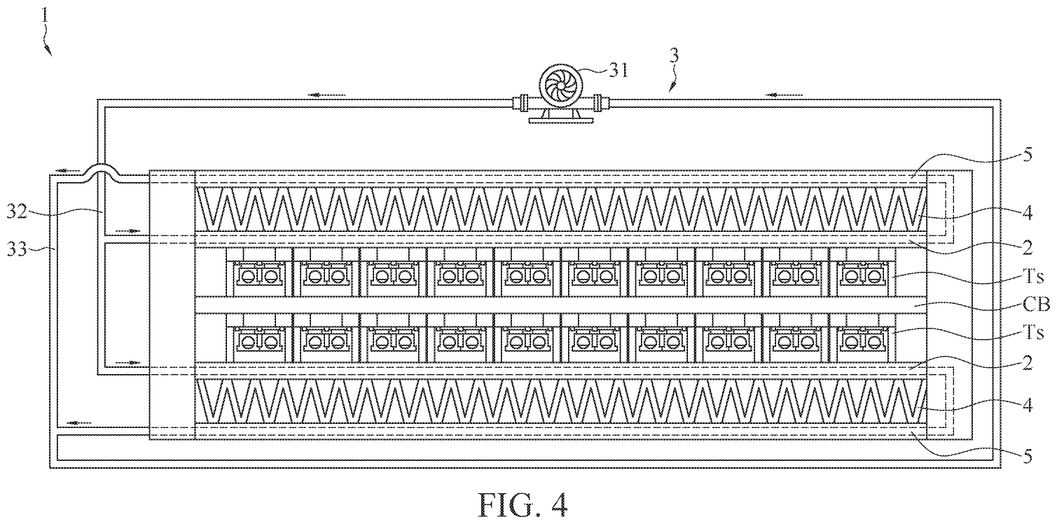

Refer to FIG. 4, which is a schematic diagram of a cooling system according to a second embodiment of the present disclosure. The main difference between an embodiment shown in FIG. 4 and the embodiment shown in FIG. 2A and FIG. 2B lies in the placement of a cooling fluid return channel 5 on the other side of the heat sink fins 4, that is, a side opposite to the cooling fluid channel 2. In other words, the cooling fluid return channel 5 and the cooling fluid channel 2 are connected to each other and form a U-shaped flow path with the heat sink fins 4 interposed between them. Moreover, the cooling fluid channel 2 is further connected to the fluid inlet channel 32, and the cooling fluid return channel 5 is further connected to the fluid outlet channel 33, establishing a closed-loop circulation path for the cooling fluid.

In this way, after the cooling fluid in the cooling fluid channel 2 absorbs a significant amount of heat, in addition to promptly transferring heat directly through the wall of the cooling fluid channel 2 to the heat sink fins 4, any residual heat that hasn't been transferred can flow through the circulation path to the cooling fluid return channel 5. Subsequently, through the cooling fluid return channel 5, the remaining heat can be further transferred to the heat sink fins 4, thereby significantly improving the heat exchange efficiency.

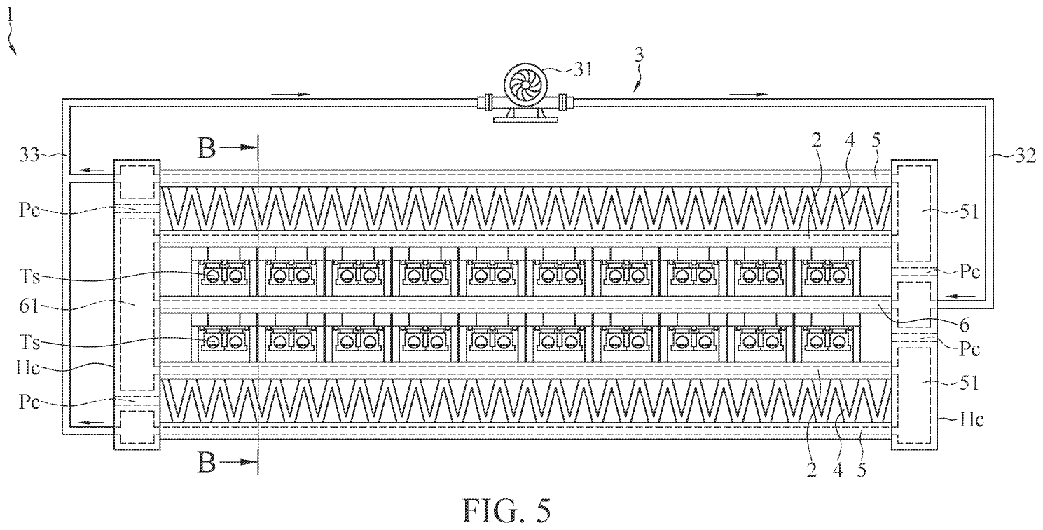

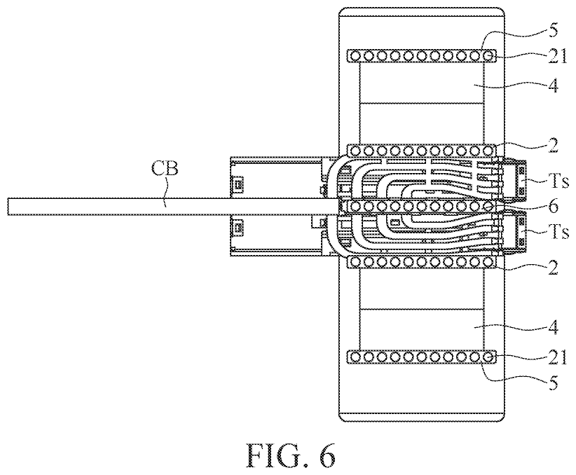

Refer to both FIG. 5 and FIG. 6. FIG. 5 is a schematic diagram of a cooling system according to a third embodiment of the present disclosure. FIG. 6 is a cross-sectional view of a line segment BB in FIG. 5. The main difference between an embodiment shown in FIG. 5 and the embodiment shown in FIG. 4 lies in that the placement of a cooling fluid supply channel 6 between the two tiers of the transceiver modules Ts. Further, two ends of each of the cooling fluid channels 2 are separately connected to the cooling fluid drive module 3 through the cooling fluid return channel 5 and the cooling fluid supply channel 6.

In other words, the cooling fluid supply channel 6 and the cooling fluid channel 2 are respectively disposed on upper and lower sides of the transceiver modules Ts, and the cooling fluid supply channel 6 is connected to the cooling fluid return channel 5 through the cooling fluid channel 2. The transceiver slots located at front ends of the transceiver modules Ts are connected to the cooling fluid supply channel 6, and rear ends of the transceiver modules Ts are electrically connected to the circuit board CB.

It is further described that the structure of the entire circulation loop includes that: an end of the fluid inlet channel 32 is connected to the fluid circulation drive member 31, and the other end is connected to an end of the cooling fluid supply channel 6. A second communication chamber 61 is configured at the other end of the cooling fluid supply channel 6, and an end of the cooling fluid channel 2 is also connected to the second communication chamber 61. Further, the other end of the cooling fluid channel 2 is connected to a first communication chamber 51, an end of the cooling fluid return channel 5 is also connected to the first communication chamber 51, and the other end of the cooling fluid return channel 5 is connected to the fluid outlet channel 33. Finally, the fluid outlet channel 33 is further connected to the fluid circulation drive member 31. In some embodiments, a plurality of fluid partitions Pc may be separately disposed in the hollow cavities Hc on both sides of the cooling fluid channel 2, the cooling fluid return channel 5, and the cooling fluid supply channel 6, to form the first communication chamber 51 and the second communication chamber 61.

In addition, the cooling fluid supply channel 6 is adjacent to a side end surface of the circuit board CB, so it can be considered as an extension segment of the circuit board CB. Moreover, as shown in FIG. 6, in some embodiments, the cooling fluid channel 2, the cooling fluid return channel 5, and the cooling fluid supply channel 6 can use aluminum extruded hollow flat tubes, inside which a plurality of parallel flow paths 21 may be disposed. The parallel flow paths 21 may extend along the side end surface of the circuit board CB. However, the parallel flow paths 21 not only increase the heat exchange surface area between the fluid and the tubes, but also reduce flow resistance to maintain a uniform flow rate, thereby significantly improving heat exchange efficiency. In other embodiments, the aluminum extruded hollow flat tubes are not limited to be designed with the plurality of parallel flow paths 21, but can also be a single flow path design.

Further, as shown in FIG. 6, an upper end surface and a lower end surface of each transceiver module Ts are respectively in contact with the cooling fluid channel 2 and the cooling fluid supply channel 6. This allows for more effective and thorough dissipation of heat from these transceiver modules Ts. In another aspect, the heat sink fins 4 may be disposed between the cooling fluid channel 2 and the cooling fluid return channel 5, allowing for more effective and thorough dissipation of heat from the heat sink fins 4 to the atmosphere.

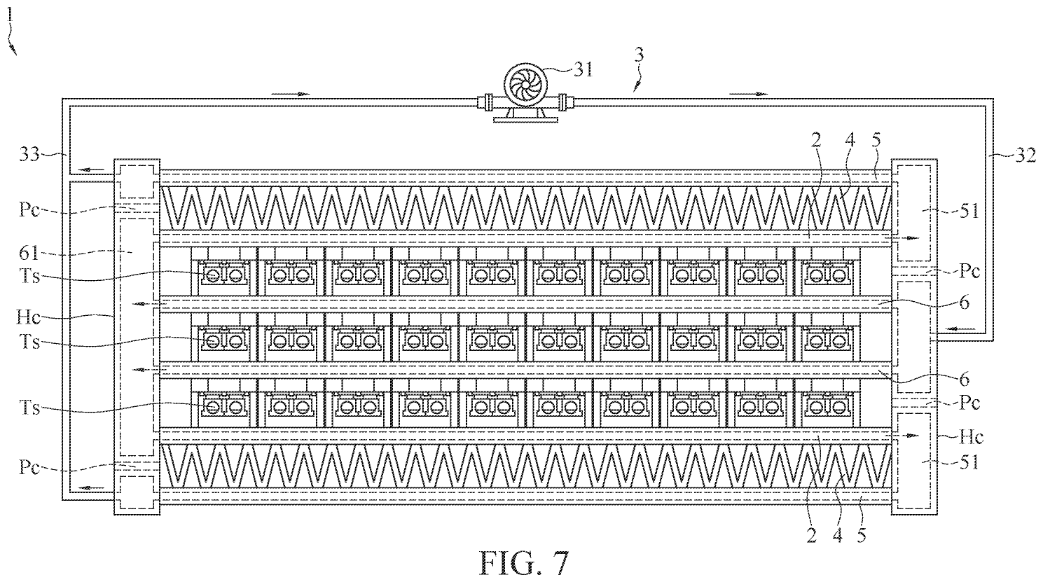

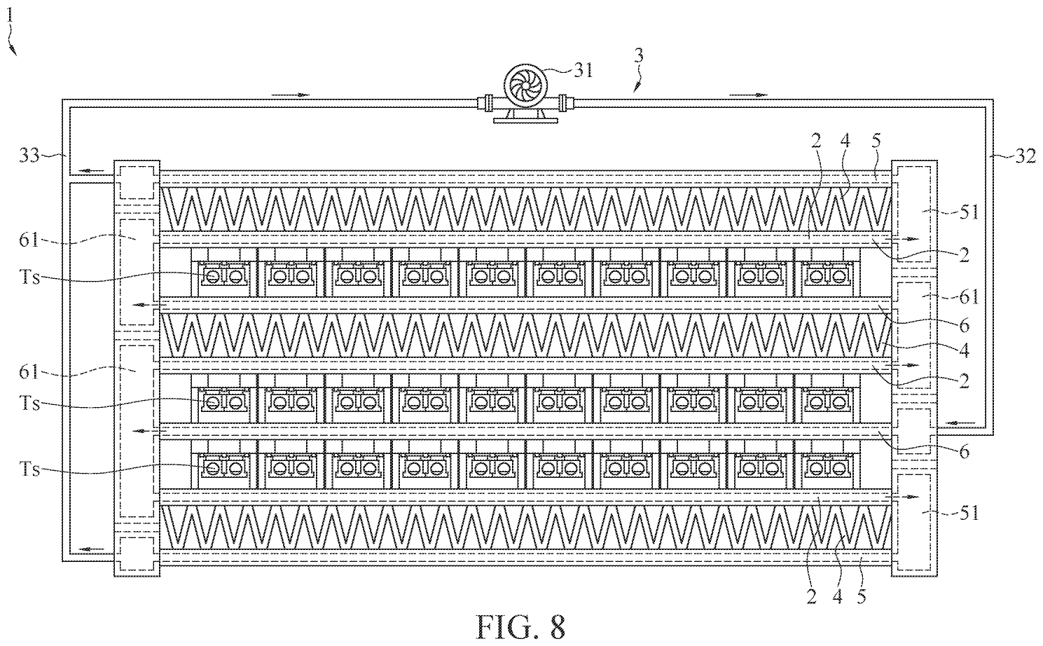

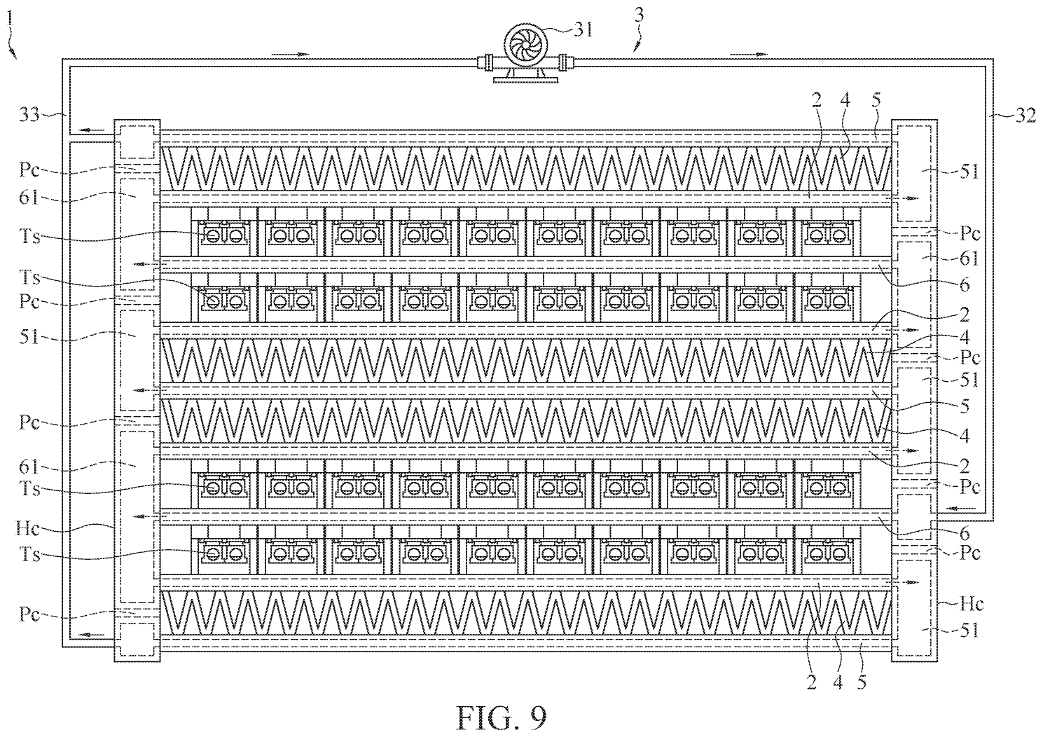

Refer to FIG. 7, FIG. 8, and FIG. 9. FIG. 7 is a schematic diagram of a cooling system according to a fourth embodiment of the present disclosure. FIG. 8 is a schematic diagram of a cooling system according to a fifth embodiment of the present disclosure. FIG. 9 is a schematic diagram of a cooling system according to a sixth embodiment of the present disclosure. These figures show various embodiments of the cooling system, including the number of layers of transceiver modules Ts, the number of channels, and the number of layers of heat sink 4, which can be increased or decreased according to actual needs, and the arrangement can be adjusted arbitrarily.

It is further described that three layers of transceiver modules Ts are configured in the embodiment shown in FIG. 7 and are adjacently stacked with each other, and one cooling fluid supply channel 6 is arranged between two adjacent layers of transceiver modules Ts. On the upper and lower sides of the top and bottom layers of the transceiver modules Ts, a cooling fluid channel 2, a heat sink fins 4, and cooling fluid return channels 5 are respectively arranged. Accordingly, as shown in FIG. 7, the cooling fluid flows from the fluid inlet channel 32 on the right side simultaneously flows into two cooling fluid supply channels 6 between two adjacent layers of transceiver modules Ts. Then, the cooling fluid further simultaneously enters the cooling fluid channels 2 located on the upper and lower sides of the three layers of transceiver modules Ts, and then flows into the uppermost layer and lowermost layer of the cooling fluid return channels 5. Finally, the cooling fluid returns to the fluid circulation drive member 31 through the fluid outlet channel 33 on the left side.

In addition, in the embodiment shown in FIG. 8, three layers of transceiver modules Ts are also configured. However, between the top layer and the middle layer of transceiver modules Ts, heat sink fins 4 are additionally configured to provide heat dissipation for each layer of transceiver modules Ts. As for the embodiment shown in FIG. 9, four layers of transceiver modules Ts are configured. The first and second layers of transceiver modules Ts are adjacent to each other, and the third and fourth layers of transceiver modules Ts are adjacent to each other, while heat sink fins 4 are configured between the second and third layers of transceiver modules Ts. In the embodiment shown in FIG. 9, a heat sink fin 4 is provided for each layer of transceiver modules Ts for heat dissipation.

As can be seen from the foregoing embodiments, in the present disclosure, various specifications and quantities of layers of transceiver modules Ts may be configured according to actual needs. The quantities of various channels for the circulation of the cooling fluid and heat sink fins 4 may also be matched according to actual needs, and the arrangement can also be adjusted and configured arbitrarily. In addition, the positions and quantities of the fluid partitions Pc arranged in the hollow cavities Hc can also be flexible according to the configuration of various tubes to form various flow patterns and communication chambers.

Some features and principles included in some embodiments are briefly described below: Aluminum extruded hollow flat tubes are used in some embodiments, with the parallel flow paths 21 inside. That is, a microchannel parallel flow configuration is used, and the hollow flat tubes are connected to the first communication chamber 51 and the second communication chamber 61, to make the hollow flat tubes in the layers become communication flow paths. Moreover, in some embodiments, in combination with the fluid circulation drive member 31, the cooling fluid may flow in the parallel flow paths 21 in the hollow flat tubes, so that active circulation heat dissipation can be formed. In this way, heat generated during operation of the transceiver modules Ts is transferred to the hollow flat tubes on an upper side or a lower side in the form of heat conduction. In addition, the cooling fluid inside the tube, due to continuous circulation, quickly carries away the heat from the transceiver module Ts in the form of heat convection, controlling the temperature of the transceiver module Ts. In addition, the heat conducted through the walls of the hollow flat tubes and the heat transferred by the cooling fluid heat convection can be dissipated into the environment through the wavy heat sink fins.

It should be noted that the cooling system provided in the above embodiments is applicable to multi-tiered transceiver modules. However, the present application can also be applied to single-tiered optical transceiver modules. In other words, in alternative embodiments, the circuit board may be provided with only a single-tier of transceiver modules.

Although the present disclosure has been described in considerable detail with reference to certain preferred embodiments thereof, the disclosure is not for limiting the scope of the disclosure. Persons having ordinary skill in the art may make various modifications and changes without departing from the scope and spirit of the disclosure. Therefore, the scope of the appended claims should not be limited to the description of the preferred embodiments described above.

What is claimed is:

1. A cooling system, used for cooling at least one transceiver module, the system comprising:
a heat sink fin;
a cooling fluid channel, arranged between the heat sink fin and the at least one transceiver module; and
a cooling fluid drive module, connected to the cooling fluid channel;
wherein the cooling fluid drive module comprises a fluid circulation drive member, a fluid inlet channel, and a fluid outlet channel; an end of the fluid inlet channel and an end of the fluid outlet channel are respectively connected to two ends of the cooling fluid channel, and an another end of the fluid inlet channel and an another end of the fluid outlet channel are connected to the fluid circulation drive member.

2. The cooling system according to claim 1, further comprising a cooling fluid return channel; wherein the cooling fluid channel and the cooling fluid return channel are separately disposed on two surfaces of the heat sink fin, and the cooling fluid channel is connected to the fluid outlet channel through the cooling fluid return channel.

3. The cooling system according to claim 2, further comprising a cooling fluid supply channel, wherein the cooling fluid supply channel and the cooling fluid channel are separately disposed on two surfaces of the at least one transceiver module, and the cooling fluid supply channel is connected to the cooling fluid return channel through the cooling fluid channel.

4. The cooling system according to claim 3, further comprising a first communication chamber and a second communication chamber, wherein the first communication chamber is disposed between the cooling fluid channel and the cooling fluid return channel; and the second communication chamber is disposed between the cooling fluid channel and the cooling fluid supply channel.

5. The cooling system according to claim 1, wherein the heat sink fin is a wavy fin.

6. The cooling system according to claim 1, wherein the cooling fluid channel comprises a hollow flat tube, and a plurality of parallel flow paths are disposed inside the hollow flat tube.

7. The cooling system according to claim 1, wherein a thermal interface material is disposed between the cooling fluid channel and the at least one transceiver module.

8. The cooling system according to claim 1, further comprising another cooling fluid channel, wherein the cooling fluid channel and the another cooling fluid channel are separately disposed on two surfaces of the at least one transceiver module; and the fluid inlet channel and the fluid outlet channel are respectively connected to two ends of the another cooling fluid channel.

9. The cooling system according to claim 8, further comprising another heat sink fin, the heat sink fin and the another heat sink fin are wavy fins; wherein the another heat sink fin is disposed on the another cooling fluid channel.

10. A communication apparatus, comprising:
a circuit board, comprising at least one transceiver module; and
a cooling system, comprising:
a heat sink fin;
a cooling fluid channel, arranged between the heat sink fin and the at least one transceiver module; and
a cooling fluid drive module, connected to the cooling fluid channel;
wherein the cooling fluid drive module comprises a fluid circulation drive member, a fluid inlet channel, and a fluid outlet channel; an end of the fluid inlet channel and an end of the fluid outlet channel are respectively connected to two ends of the cooling fluid channel, and an another end of the fluid inlet channel and an another end of the fluid outlet channel are connected to the fluid circulation drive member.

11. The communication apparatus according to claim 10, further comprising a cooling fluid return channel, wherein the cooling fluid channel and the cooling fluid return channel are separately disposed on upper and lower sides of the heat sink fin and are connected to each other.

12. The communication apparatus according to claim 11, wherein the cooling fluid drive module comprises a fluid circulation drive member, a fluid inlet channel, and a fluid outlet channel; two ends of the cooling fluid channel are respectively connected to an end of the fluid inlet channel and an end of the cooling fluid return channel; an another end of the cooling fluid return channel is connected to an end of the fluid outlet channel; and an another end of the fluid inlet channel and an another end of the fluid outlet channel are respectively connected to the fluid circulation drive member.

13. The communication apparatus according to claim 11, wherein the at least one transceiver module is a plurality of transceiver modules, and the cooling system further comprises a cooling fluid supply channel; the plurality of transceiver modules are respectively disposed on upper and lower sides of the cooling fluid supply channel, and the cooling fluid supply channel is adjacent to a side end surface of the circuit board; the cooling fluid supply channel is connected to the cooling fluid return channel through the cooling fluid channel.

14. The communication apparatus according to claim 13, further comprising a first communication chamber and a second communication chamber, wherein the first communication chamber is disposed between the cooling fluid channel and the cooling fluid return channel; and the second communication chamber is disposed between the cooling fluid channel and the cooling fluid supply channel.

15. The communication apparatus according to claim 10, further comprising a housing and at least one fan, wherein the cooling system, the circuit board, and the at least one fan are disposed in the housing, the cooling system and the at least one fan are separately disposed at two corresponding ends of the housing.

16. The communication apparatus according to claim 10, wherein the cooling fluid channel comprises a hollow flat tube, a plurality of parallel flow paths are disposed inside the flat tube, and the parallel flow paths extend along a side end surface of the circuit board.

17. The communication apparatus according to claim 10, wherein a thermal interface material is disposed between the cooling fluid channel and the at least one transceiver module.

18. A cooling system, used for cooling a plurality of transceiver modules configured in multi-tiered arrangement, the system comprising:
a plurality of heat sink fins;
a plurality of cooling fluid channels; and
a cooling fluid drive module, connected to the plurality of cooling fluid channels;
wherein the plurality of cooling fluid channels are respectively arranged with the plurality of heat sink fins, and one of the plurality of cooling fluid channels is sandwiched between one tier of the plurality of transceiver modules and one of the plurality of heat sink fins.

19. The cooling system according to claim 18, wherein the plurality of transceiver modules are configured in two tiers, and the plurality of cooling fluid channels are arranged in two corresponding surfaces of the plurality of transceiver modules.

20. The cooling system according to claim 18, further comprising a plurality of cooling fluid return channels and a cooling fluid supply channel; wherein the plurality of cooling fluid channels and the plurality of cooling fluid return channels are separately disposed on two corresponding surfaces of the plurality of heat sink fins; the cooling fluid supply channel is arranged between the two tiers of the transceiver modules; two ends of each of the plurality of cooling fluid channels are separately connected to the cooling fluid drive module through the plurality of cooling fluid return channels and the cooling fluid supply channel.
